(19) United States
(12) Patent Application Publication
(10) Pub. No.: US 2016/0276523 A1
(43) Pub. Date: Sep. 22, 2016

(54) SEMICONDUCTOR LIGHT-EMITTING ELEMENT AND MANUFACTURING METHOD THEREOF

(71) Applicant: KABUSHIKI KAISHA TOSHIBA, Tokyo (JP)

(72) Inventors: Jongil HWANG, Nonoichi Ishikawa (JP); Hiroshi KATSUNO, Komatsu Ishikawa (JP)

(21) Appl. No.: 15/060,530

(22) Filed: Mar. 3, 2016

(30) Foreign Application Priority Data
Mar. 16, 2015 (JP) 2015-051703

(51) Int. Cl. H01L 33/00; H01L 33/06; H01L 33/36; H01L 33/18; H01L 33/32; H01L 33/20

(52) U.S. Cl. CPC H01L 33/007; H01L 33/0012; H01L 33/32; H01L 33/20; H01L 33/36; H01L 33/18; H01L 33/06; H01L 33/0079; H01L 2933/0066

(57) ABSTRACT

A semiconductor light-emitting element includes a substrate having a first side and a second side, a first semiconductor layer of a first conductivity type on the first side of the substrate, a second semiconductor layer of a second conductivity type between the substrate and the first semiconductor layer, a third semiconductor layer between the first semiconductor layer and the second semiconductor layer, and a metal layer between the substrate and the second semiconductor layer. The substrate has a first surface on the first side facing the metal layer and a second surface on the second side opposite to the first surface, and the second surface is convex.

### CROSS-REFERENCE TO RELATED APPLICATION

This application is based upon and claims the benefit of priority from Japanese Patent Application No. 2015-051703, filed Mar. 16, 2015, the entire contents of which are incorporated herein by reference.

### FIELD

Embodiments described herein relate generally to a semiconductor light-emitting element and a manufacturing method thereof.

### BACKGROUND

A semiconductor light-emitting element such as a light-emitting diode (LED) is used in a variety of applications such as in display devices, lighting devices, or the like. When such a semiconductor light-emitting element is formed on a silicon substrate for purposes of mass production, defects and cracks caused by differences in device layer lattice constants, a thermal expansion coefficients, and the like will typically occur. These defects and cracks cause the light-emitting characteristics of the semiconductor light-emitting element to deteriorate and the output efficiency of the semiconductor light-emitting element to be lowered.

### DESCRIPTION OF THE DRAWINGS

FIGS. 1A to 1D are schematic views which illustrate a semiconductor light-emitting element according to an embodiment.

FIG. 2 is a schematic sectional view which illustrates the semiconductor light-emitting element according to the embodiment and element planar warpage or bowing.

FIGS. 3A to 3G are schematic sectional views which illustrate a method of manufacturing the semiconductor light-emitting element according to the embodiment.

FIG. 4 is a graph which illustrates warpage characteristics of the semiconductor light-emitting element according to the embodiment.

FIG. 5 is a graph which depicts measured lattice length of a layer of the semiconductor light-emitting element according to the embodiment.

FIG. 6 is a graph which depicts a relationship between warpage at different stages in the manufacture of the semiconductor light-emitting element according to the embodiment.

FIG. 7 is a graph that depicts a change in the relationship of warpage at different point in the manufacturing with changes in processing temperature of the semiconductor light-emitting element according to the embodiment.

### DETAILED DESCRIPTION

In general, according to one embodiment, a semiconductor light-emitting element includes a substrate having a first and second side, a first semiconductor layer of a first conductivity type on the first side of the substrate, a second semiconductor layer of a second conductivity type between the substrate and the first semiconductor layer, a third semiconductor layer between the first semiconductor layer and the second semiconductor layer, and a metal layer between the substrate and the second semiconductor layer. The substrate has a first surface on the first side facing the metal layer and a second surface on the second side of the substrate opposite to the first surface, and the second surface is convex (outwardly bowed such that central portion of the second surface extends beyond the peripheral portions of the second surface along a direction normal to a plane that is tangent to the central portion of the second surface).

Hereinafter, example embodiments of the present disclosure will be described with reference to drawings.

The drawings are schematic or conceptual, and not necessarily to scale. In some depictions, elements may be exaggerated, minimized, or omitted for clarity of explanation. Furthermore, the relative dimensions of elements in the same drawing are not necessarily those in a practical device. Similarly, the same element depicted in different drawings may be presented having different dimensions or relative sizes for clarity of explanation.

In the present disclosure, a description of elements described with respect to a previously discussed embodiment or drawing may be omitted in some instances when appropriate.

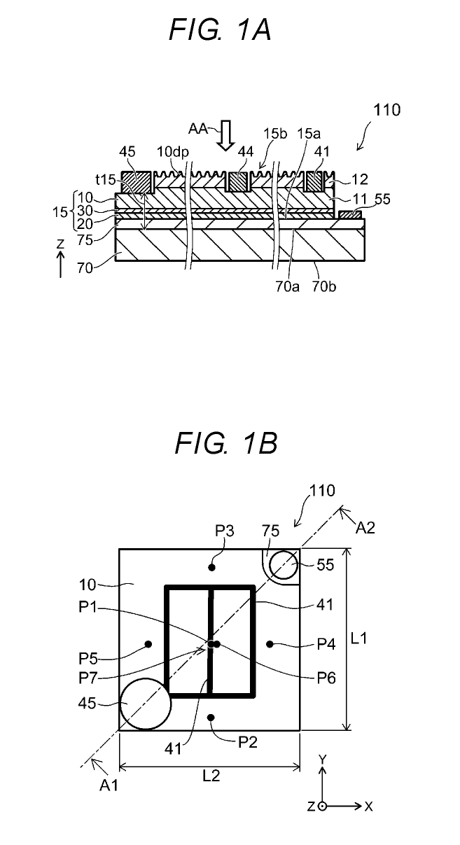

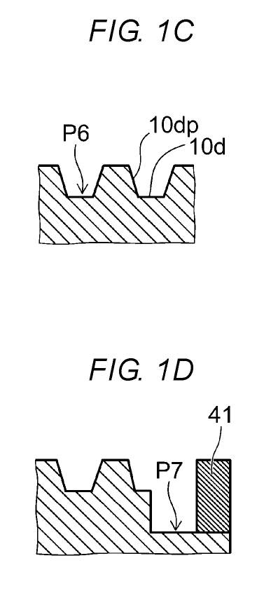

FIGS. 1A to 1D are schematic views which illustrate a semiconductor light-emitting element according to one embodiment.

FIG. 1A is a cross-sectional view taken along line A1-A2 of FIG. 1B. FIG. 1B is a plan view which is viewed along an arrow AA of FIG. 1A. FIG. 1C is a cross-sectional view which enlarges a region including a sixth position P6 indicated in FIG. 1B. FIG. 1D is a cross-sectional view which enlarges a region including a seventh position P7 indicated in FIG. 1B.

As shown in FIG. 1A, a semiconductor light-emitting element 110 includes a substrate 70, a first semiconductor layer 10, a second semiconductor layer 20, a third semiconductor layer 30, and a metal layer 75.

The first semiconductor layer 10 has a first conductivity type. The second semiconductor layer 20 is provided between the substrate 70 and the first semiconductor layer 10. The second semiconductor layer 20 has a second conductivity type.

For example, the first conductivity type is an n-type, and the second conductivity type is a p-type. However, the first conductivity type may instead be the p-type, and the second conductivity type may instead be the n-type. In a following description of semiconductor light-emitting element 110, the first conductivity type is set as the n-type, and the second conductivity type is set as the p-type.

The third semiconductor layer 30 is provided between the first semiconductor layer 10 and the second semiconductor layer 20. The third semiconductor layer 30 includes a light-emitting layer. The third semiconductor layer 30 may be described as the light-emitting portion of semiconductor light-emitting element 110.

For the first semiconductor layer 10, the second semiconductor layer 20, and the third semiconductor layer 30, for example, a nitride semiconductor is used. The first semiconductor layer 10 includes, for example, a gallium nitride (GaN) layer 11 of n-type. The GaN layer 11 contains, for example, Si as a dopant/impurity. The second semiconductor layer 20 includes, for example, a p-type GaN layer. The second semiconductor layer 20 may include p-type aluminum gallium nitride (AlGaN). The second semiconductor layer 20 contains, for example, Mg as a dopant/impurity. The third semiconductor layer 30 may include a well layer and a barrier layer. The well layer contains, for example, indium gallium nitride (InGaN). The barrier layer contains, for example, GaN. The barrier layer may instead contain InGaN having a composition ratio of indium (In) lower than a composition ratio of indium (In) in the well layer. That is, ratio of indium atoms to total atoms in the barrier layer material is lower than the ratio of indium atoms to total atoms in well layer material.

In the depicted example in FIG. 1A, a low impurity concentration layer 12 is provided on first semiconductor layer 10. Conceptually, the low impurity concentration layer 12, when included, can also be considered to be a portion of first semiconductor 10, and thus also a portion of the stacked body 15. When included, the low impurity concentration layer 12 is adjacent to the GaN layer 11 in the stacking direction. An impurity concentration (an impurity concentration of the first conductivity type) in the low impurity concentration layer 12 is lower than an impurity concentration (an impurity concentration of the first conductivity type) in the GaN layer 11. The low impurity concentration layer 12 contains at least one of GaN, AlGaN, and AlN. For example, the low impurity concentration layer 12 may be GaN. The low impurity concentration layer 12 may be referred to in some instances as a “buffer layer.” In some embodiments of the semiconductor light-emitting element 110, the low impurity concentration layer 12 may be omitted. In such embodiments, GaN layer 11 may be at the upper surface of the first semiconductor layer 10 with no buffer layer disposed thereon.

The first semiconductor layer 10, the second semiconductor layer 20, and the third semiconductor layer 30 are included in a stacked body 15. That is, these layers are provided stacked one on top of each other in the depicted order. When the low impurity concentration layer 12 is provided, the low impurity concentration layer 12 can also be consider to be included within the stacked body 15.

The metal layer 75 is provided between the substrate 70 and the second semiconductor layer 20. The metal layer 75 is, for example, a bonding layer. For example, the second semiconductor layer 20 is electrically connected to the metal layer 75.

The semiconductor light-emitting element 110 further includes a first electrode 45 and a second electrode 55.

A portion of the first semiconductor layer 10 is between the first electrode 45 and the metal layer 75. The portion need not be the full thickness of first semiconductor layer 10 along the Z direction and some portions of the first semiconductor layer 10 may be at a level (along the Z direction) that is higher (along the Z-direction from the substrate 70) than a level of the surface of the first electrode 45 that contacts the portion of the first semiconductor layer 10. The portion of the first semiconductor layer 10 is between the first electrode 45 and the third semiconductor layer 30.

The second electrode 55 is electrically connected to the metal layer 75. In this example, the metal layer 75 is arranged between the second electrode 55 and the substrate 70.

A direction from the substrate 70 to the second semiconductor layer 20 is set as a Z axis direction (see FIG. 1A). One direction perpendicular to the Z axis direction is set as an X axis direction (see FIG. 1B). A direction perpendicular to the Z axis direction and the X axis direction is set as a Y axis direction (see FIG. 1B). The Z axis direction may be referred to in some instances as a first direction.

The metal layer 75 is provided on the substrate 70, and the second electrode 55 is provided on a portion of the metal layer 75. The second semiconductor layer 20, the third semiconductor layer 30, and the first semiconductor layer 10 are provided on another portion of the metal layer 75 in this order. That is, here the second electrode 55 is directly contacting the metal layer 75 on a portion of the metal layer which extends beyond the stacked body 15 in a direction that is parallel to the X-Y plane, which here corresponds to a plane of the upper surface of the substrate 70.

In the present disclosure, it should be noted that description stating “a first element being provided on a second element” or grammatical variations thereof encompasses arrangements in which another element or elements (e.g., a third element, a fourth element, etc.) is/are interposed between the first and second elements and also arrangements in which the first and second elements are in direct contact with each other without any other element being interposed therebetween. Similarly, it should be noted that when description states: “a second element being formed on a first element” or grammatical variations thereof includes encompasses arrangements or processes in which another element or elements is/are interposed between the first and second elements and also arrangements in which the first and second elements are in direct contact with each other without any other element being interposed therebetween.

In FIG. 1A, a conductive layer 41 is further provided in semiconductor light-emitting element 110. A portion of the first semiconductor layer 10 is provided between the conductive layer 41 and the third semiconductor layer 30. The conductive layer 41 is electrically connected to the first electrode 45. The conductive layer 41 is, for example, a thin wire electrode.

A voltage is applied between the first electrode 45 and the second electrode 55. A current is supplied to the third semiconductor layer 30 through the first semiconductor layer 10, the metal layer 75, and the second semiconductor layer 20. Light is emitted from the third semiconductor layer 30. The light is emitted from the first semiconductor layer 10 side to the outside of the semiconductor light-emitting element 110. The semiconductor light-emitting element 110 is, for example, an LED.

A surface roughness portion 10dp is provided on a surface of the stacked body 15, for example, the uppermost surface of the stacked body 15 along the Z-direction from substrate 70. Light extraction efficiency is improved by the surface roughness portion 10dp as it discourages interfacial reflections. The surface roughness portion 10dp may also be referred to as “a plurality of concave-convex portions.”

In an example embodiment, the metal layer 75 contains at least one of nickel (Ni), silver (Ag), platinum (Pt), and tin (Sn). In another example, the metal layer 75 may comprises as metal alloys of nickel, silver, platinum, or tin. In other examples, the metal layer 75 may be metallic nickel, metallic silver, metallic platinum, or metallic tin. The metal layer 75 may comprise a stack of different metal layers. The substrate 70 in an example contains at least one of Si (e.g., single crystalline silicon), aluminum nitride, and Al_{2-x-y}InₓGa_{y}O₃ (0≦x, y≦1).

For example, a silicon substrate or the like can be used for the substrate 70. The substrate 70 may instead be, for example, a metal substrate or the like.

A shape of the semiconductor light-emitting element 110 in a X-Y plane is, for example, rectangular (e.g., a square). An extending direction of one side of the rectangle is set as the X axis direction. An extending direction of another side of the rectangle is set as the Y axis direction. The semiconductor light-emitting element 110 has a length L1 in the Y axis direction and a length L2 in the X axis direction. Here, at least one of the length L1 and the length L2 corresponds to a maximum chip dimension (chip size) of the semiconductor light-emitting element 110. When a shape of the semiconductor light-emitting element 110 in the X-Y plane is a square, the length L1 is equal to the length L2, and the maximum chip dimension is set as the length L1. When the shape of the semiconductor light-emitting element 110 in the X-Y plane is not a square, the length L1 can be longer than the length L2, and the maximum chip dimension would be set in this instance to the length L1.

As shown in FIG. 1A, the substrate 70 has a first surface 70a, and a second surface 70b. The first surface 70a is a surface on a side of the metal layer 75. That is, the first surface 70a is the surface of the substrate 70 on which the metal layer 75 is most directly disposed. The second surface 70b is a surface opposite to the first surface 70a. The stacked body 15 has a third surface 15a and a fourth surface 15b. The third surface 15a is a surface on the side (a side of the substrate 70) of the metal layer 75. That is, the third surface 15a is the lowest surface of the stacked body 15 along the z-axis from the substrate 70 (first surface 70a). The fourth surface 15b is a surface opposite to the third surface 15a. The third surface 15a is, for example, a surface on a side of the second semiconductor layer 20. The fourth surface 15b is, for example, a surface on a side of the first semiconductor layer 10. That is, the fourth surface 15b is the highest surface of the stacked body along the z-axis from the substrate 70 (first surface 70a). In some instances, fourth surface 15b may be referred to as “the upper surface of the stacked body.” For example, the fourth surface 15a may be an uppermost surface of first semiconductor layer 10.

The semiconductor light-emitting element 110 is a thin film type light-emitting element. In the fabrication of such an element, a substrate which is used for a growth of a semiconductor layer is removed from layer stack that ultimately becomes the semiconductor light-emitting element 110. By such a process, a distance t15 between the first electrode 45 and the metal layer 75 can be made relatively short. The distance t15 is, for example, between 0.5 micrometers (μm) and 5 μm. The thin film type light-emitting element can be adopted, whereby high heat dissipation property is obtained. Accordingly, a high efficiency is obtained.

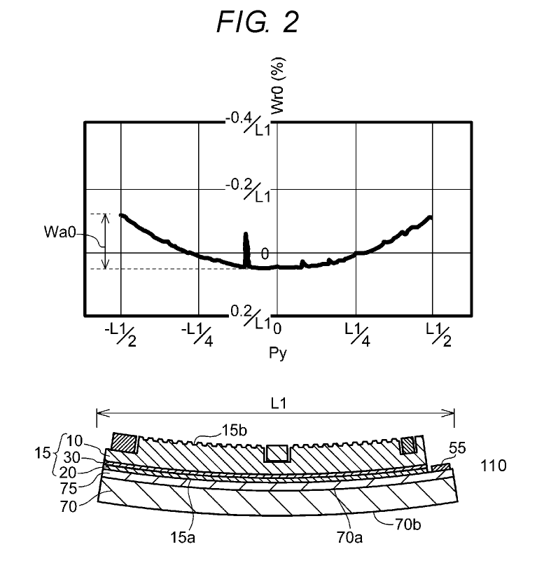

In the semiconductor light-emitting element 110, there is likely to be a device warpage (see e.g. FIG. 2).

FIG. 2 is a schematic cross-sectional view which illustrates the semiconductor light-emitting element depicted in FIGS. 1A-1D having warpage. FIG. 2 shows the warpage of the semiconductor light-emitting element 110. In the graph of the upper portion of FIG. 2, a horizontal axis represents a position Py in the Y axis direction. A vertical axis represents a warping rate Wr0 (percent %) of the semiconductor light-emitting element 110. The warping rate Wr0 is a value corresponding to an overall warping amount Wa0 of the second surface 70b (lower surface) of the substrate 70. The warping rate Wr0 is a value obtained by normalizing measured warping rate by the measured overall warping amount Wa0 (max-to-min distance) and a chip size (length L1) of the semiconductor light-emitting element 110. That is, the warping rate Wr0 is Wa1/L1, where Wa1 is the local warping amount (a measured distance from a zero warp plane at specific Py values). Warpage is negative when the second surface 70b of the substrate 70 is convex shaped, and is positive when the second surface 70b of the substrate 70 has a concave shape. When the warpage is negative, a fourth (upper) surface 15b of the stacked body 15 has a concave shape, and when the warpage is positive, the fourth surface 15b of the stacked body 15 has a convex shape.

As shown in FIG. 2, the semiconductor light-emitting element 110 has negative warpage. The second surface 70b of the substrate 70 has a convex shape. As described further below, it is possible to provide stress in the stacked body 15 (for example, the first semiconductor layer 10) by the negative warpage. The warpage may result from the manufacturing process of the semiconductor light-emitting element 110.

Hereinafter, an example of a method of manufacturing the semiconductor light-emitting element 110 will be described.

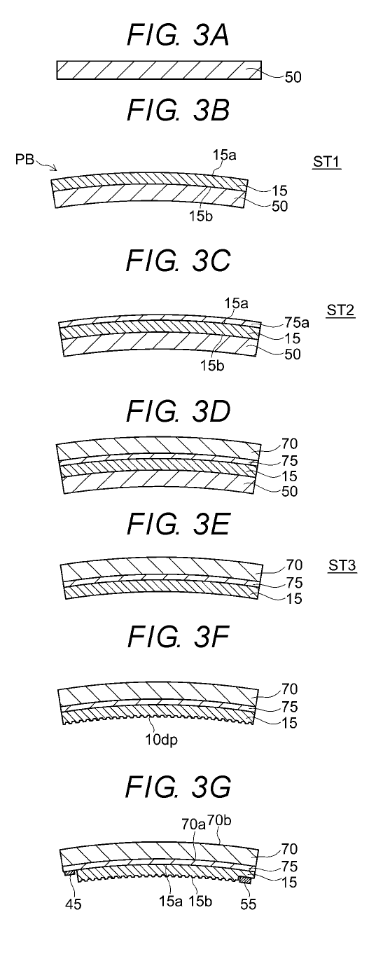

FIGS. 3A to 3G are schematic sectional views which illustrate the method of manufacturing the semiconductor light-emitting element according to an embodiment.

As shown in FIG. 3A, a substrate 50 is prepared. The substrate 50 is, for example, a silicon substrate. The substrate 50 is substantially flat, that is warpage of the substrate 50 is small or at least locally so over a chip size planar area.

As shown in FIG. 3B, the stacked body 15 is formed on the substrate 50. That is, the first semiconductor layer 10 is formed on the substrate 50 (for example, silicon substrate). The third semiconductor layer 30 is formed on the first semiconductor layer 10. The second semiconductor layer 20 is formed on the third semiconductor layer 30. In this example, the low impurity concentration layer 12 is formed on the substrate 50, and the remainder of the first semiconductor layer 10 (e.g., GaN layer 11) is formed on the low impurity concentration layer 12. The low impurity concentration layer 12 is, for example, a buffer layer.

In the formation, for example, a metal organic chemical vapor deposition (MOCVD) method is used. A temperature for formation is, for example, between 600° C. and 1200° C. The forming temperature may be varied layer to layer. After this growth/deposition process, the temperature of the substrate 50 and the layers formed thereon is returned to a room temperature.

In general, when forming a nitride semiconductor on the silicon substrate, warpage is generated. This warpage is typically downwardly convex shaped. The warpage is caused by differences in thermal expansion coefficients between the substrate 50 and the stacked body 15, differences in lattice constants between the substrate 50 and the stacked body 15, and the like. At this time, a tensile stress is applied to the stacked body 15, and cracking may easily occur. The tensile stress is a stress in a direction along a layer surface of the semiconductor layer directed outwardly.

However, it is possible to accumulate a compressive stress on the buffer layer and the stacked body 15 by forming a buffer layer of an appropriate condition. The compressive stress is a stress in a direction along a layer surface of the semiconductor layer directed inwardly. In this embodiment, the buffer layer of an appropriate condition is used.

In FIG. 3B, a state that the temperature is returned to a room temperature after growth is shown. By the compressive stress, upwardly convex warpage is generated in the processed body PB which includes the substrate 50, the buffer layer (low impurity concentration layer 12), and the stacked body 15. At this time, the compressive stress is applied to the stacked body 15. As a result, cracking is suppressed.

A process shown in FIG. 3B (formation of stacked body 15 on substrate 50) is set as a first step ST1.

As shown in FIG. 3C, a metal film 75a is formed on the stacked body 15. That is, the metal film 75a (which is at least a portion of the metal layer 75) is formed on the second semiconductor layer 20. After a formation of the metal film 75a, upwardly convex warpage is maintained. The process shown in FIG. 3C (formation of metal layer 75a on stacked body 15) is set to be a second step ST2.

As shown in FIG. 3D, the substrate 70 is bonded to a processed body PB. For example, another metal film is formed on a surface of the substrate 70 and the metal film on substrate 70 and metal film 75a (or another metal film formed on metal film 75a) are bonded to each other. These metal films become the metal layer 75. Even after the bonding, the upwardly convex warpage is maintained.

As shown in FIG. 3E, the substrate 50 is removed. In a removal of the substrate 50, for example, at least one of grinding and etching is used. Even after the removal of the substrate 50, the upwardly convex warpage of the remaining film stack is maintained. At this time, some portion of the buffer layer (low impurity concentration layer 12) may be removed such that at least a portion of the low impurity concentration layer 12 is left.

A process shown in FIG. 3E (removal of substrate 50) is set as a third step ST3.

As shown in FIG. 3F, the surface roughness portion 10 dp is formed on a surface (for example, buffer layer, that is, a surface of the low impurity concentration layer 12) of the stacked body 15. When the buffer layer (low impurity concentration layer 12) is removed, the surface roughness portion 10 dp is formed on a surface of a remaining portion of the first semiconductor layer 10 (e.g., GaN layer 11). In a formation of the surface roughness portion 10 dp, for example, a wet or dry etching can be used. Even after the formation of the surface roughness portion 10 dp, the upwardly convex warpage is maintained.

As shown in FIG. 3G, portions of the stacked body 15 are removed. Accordingly, parts of the first semiconductor layer 10 are exposed. In this example, a portion of the metal layer 75 is also exposed by removal of portions of the stacked body 15. The first electrode 45 and the second electrode 55 are formed. Even after a formation of these electrodes, the upwardly convex warpage is maintained.

In this manner, the semiconductor light-emitting element 110 is formed. For example, the stacked body 15 formed on the substrate 50 of a wafer shape is divided into a plurality of regions, and a plurality of semiconductor light-emitting elements 110 are obtained. As described above, in this manufacturing method, the metal layer 75 is formed on the second semiconductor layer 20. Then, the first electrode 45 is formed on a surface of the first semiconductor layer 10 after the substrate 50 (e.g., silicon substrate) has been removed.

FIGS. 3A to 3G described above schematically show a portion of one semiconductor light-emitting element 110. Warpage is exaggerated in the depictions.

Hereinafter, an example of a result of measuring warpage will be described.

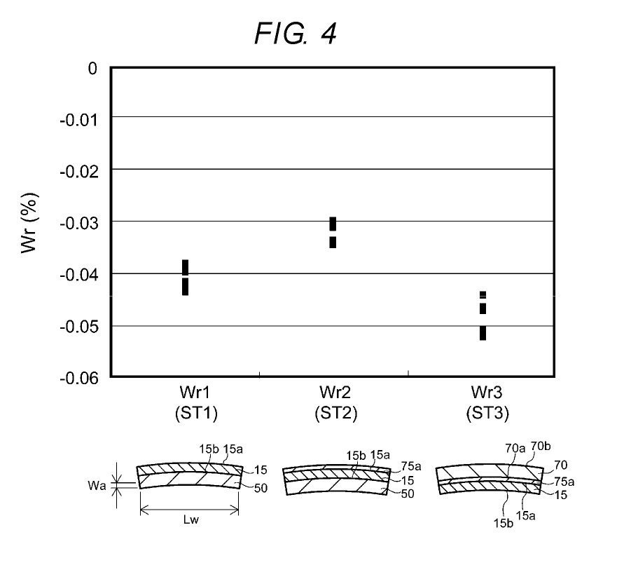

FIG. 4 is a graph which illustrates characteristics of a semiconductor light-emitting element according to an embodiment.

A vertical axis in FIG. 4 represents a warping rate Wr (%). A size Lw of the substrate 50 (wafer) is the same as a size of the substrate 70 before division. The warping rate Wr is a value obtained by normalizing the warpage amount Wa using the size Lw of the substrate 50 (or the size of the substrate 70 before division). A direction orthogonal to a surface of a wafer at a center of the wafer corresponds to the Z axis direction. The warpage amount Wa is a vertical distance (height difference) between an outer edge of the wafer and a center of the wafer in the Z axis direction. A positive warpage amount Wa corresponds to downwardly convex warpage. A negative warpage amount Wa corresponds to upwardly convex warpage. A horizontal axis in FIG. 4 corresponds to the first step ST1, the second step ST2, and the third step ST3. First to third warping rates Wr1 (%) to Wr3 (%) corresponding to the first step ST1, the second step ST2, and the third step ST3, respectively, are shown in FIG. 4.

As shown in FIG. 4, the first warping rate Wr1 is between −0.044% and −0.038% after the first step ST1 (growth of the stacked body 15). Large upwardly convex warpage is generated.

The second warping rate Wr2 is between −0.035% and −0.03% after the second step ST2 (formation of a metal film 75a, which is a portion of the metal layer 75). The upwardly convex warpage is maintained.

After the third step ST3 (removal of the substrate 50), the third warping rate Wr3 is between −0.052% and −0.04%. Upwardly convex warpage is generated in this step.

As described above, in the manufacturing method, the upwardly convex warpage after a semiconductor layer is formed on the substrate 50 (after the first step ST1) is maintained even after removing the substrate 50 (after the third step ST3).

Accordingly, cracking will be suppressed during manufacturing at least until the third step ST3 (removal of the substrate 50). That is, compressive stress is applied to the stacked body 15 until the third step ST3 (removal of the substrate 50).

Then, as described with respect to FIG. 2, negative warpage is obtained even in the semiconductor light-emitting element 110 after forming an electrode. The compressive stress is applied to the stacked body 15 in the semiconductor light-emitting element 110 by the negative warpage. Defects or cracks thus hardly occur in the stacked body 15 (for example, at least one of the first semiconductor layer 10, the second semiconductor layer 20, and the third semiconductor layer 30) due to such compressive stress. Accordingly, high manufacturing efficiency is obtained.

When a crack occurs, a yield is lowered and productivity is lowered. Furthermore, easy occurrence of cracks lowers reliability in a use of the semiconductor light-emitting element in some cases. Since defects or cracks are suppressed in the embodiment, productivity is higher. Furthermore, changes in device characteristics due to cracking are suppressed. Accordingly, higher device reliability may be obtained.

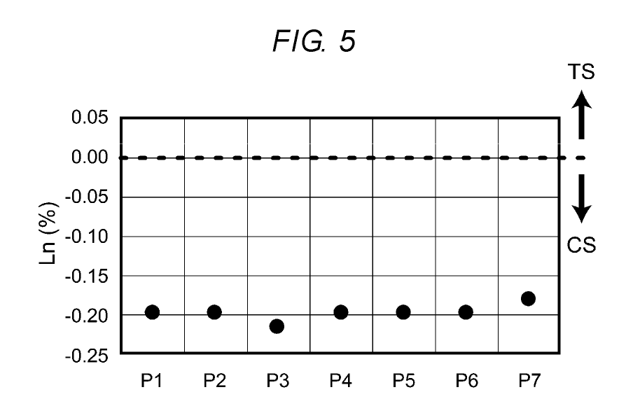

FIG. 5 is a graph which depicts measured lattice length of a layer of the semiconductor light-emitting element according to the embodiment.

FIG. 5 shows a result of measuring a lattice length of the first semiconductor layer 10 (GaN layer) in first to seventh positions P1 to P7 shown in FIG. 1B. The vertical axis represents a normalized lattice length Ln (%). When a measured value of the lattice length is set as Lm, and a lattice constant of GaN is set as Lc, the normalized lattice length Ln is {(Lm−Lc)/Lc}×100. The lattice constant Lc is a specific physical property value of GaN, and is a lattice length of unstrained GaN.

In this example, a c axis of GaN extends substantially along the Z axis direction. The lattice length and the lattice constant described above substantially correspond to an “a” axis lattice spacing. That is, the lattice length is a lattice length in the second direction (for example, the X axis direction) which intersects with the first direction (for example, the Z axis direction) from the metal layer 75 to the second semiconductor layer 20.

When the normalized lattice length Ln is positive, a tensile stress TS is applied to the GaN layer 11 of the first semiconductor layer 10. When the normalized lattice length Ln is negative, compressive stress CS is applied to the GaN layer 11 of the first semiconductor layer 10.

As shown in FIG. 5, at any of the first to seventh positions P1 to P7, the normalized lattice length Ln is negative. That is, the compressive stress is applied to the GaN layer 11 at each position. The normalized lattice length Ln is between −0.22% and −0.17%.

In this manner, in the semiconductor light-emitting element 110, the lattice length (a measured value Lm) of the GaN layer 11 in the second direction is smaller than the lattice constant Lc of GaN. In the GaN layer 11, the compressive stress is maintained and defects or cracks hardly occur.

As described earlier, in the manufacturing method, upwardly convex warpage after forming a semiconductor layer on the substrate 50 (after the first step ST1) is maintained even after the substrate 50 is removed (after the third step ST3). Hereinafter, a relationship between the first warping rate Wr1 after the first step ST1 and the third warping rate Wr3 after the third step ST3 will be described.

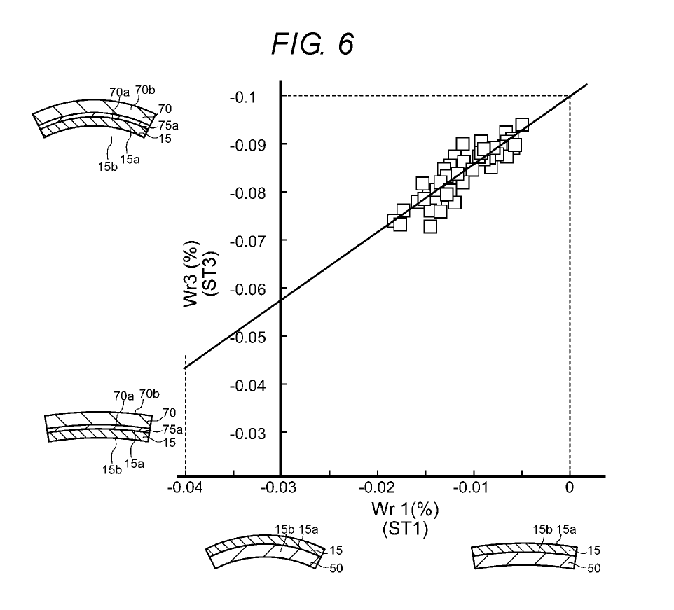

FIG. 6 is a graph which depicts a relationship between warpage at different stages in the manufacture of the semiconductor light-emitting element according to the embodiment.

A horizontal axis in FIG. 6 represents a first warping rate Wr1 (%) after the first step ST1. When an absolute value of the first warping rate Wr1 is large, warpage is large. In the embodiment, the first warping rate Wr1 is negative. At this time, a third surface 15a of the stacked body 15 has a convex shape, and a fourth surface 15b has a concave shape. A vertical axis in FIG. 6 represents the third warping rate Wr3 (%) after the third step ST3. When an absolute value of the third warping rate Wr3 is large, warpage is large. In the embodiment, the third warping rate Wr3 is negative. At this time, the third surface 15a of the stacked body 15 has a convex shape, and the fourth surface 15b has a concave shape. Then, the first surface 70a of the substrate 70 has a concave shape, and the second surface 70b has a convex shape. A state that the first warping rate Wr1 is approximately −0.04%, and the third warping rate Wr3 is approximately −0.047% as shown in FIG. 6 corresponds to a condition shown in FIG. 4.

As shown in FIG. 6, the first warping rate Wr1 is correlated with the third warping rate Wr3. When an absolute value of the first warping rate Wr1 is large, an absolute value of the third warping rate Wr3 is small.

In FIG. 6, when an absolute value of the first warping rate Wr1 after the first step ST1 is large, a compressive stress in the stacked body 15 (for example, the first semiconductor layer 10) is large. When the absolute value of the first warping rate Wr1 after the first step ST1 is small, the compressive stress in the stacked body 15 (for example, the first semiconductor layer 10) is small.

From FIG. 6, for example, it is demonstrated by extrapolation that an absolute value of the third warping rate Wr3 after the third step ST3 is large when the first warping rate Wr1 after the first step ST1 is 0. That is, even when warpage does not occur after the first step ST1, warpage still occurs after the third step ST3. This is because warpage occurs in a bonding step or a removal step of the substrate 50. As a result of examination, it is considered that the warpage after the third step ST3 results largely in the bonding step.

On the other hand, from FIG. 6, it is known that the absolute value of the third warping rate Wr3 after the third step ST3 is small when the absolute value of the first warping rate Wr1 after the first step ST1 is large and warpage is large. That is, even when the warpage after the first step ST1 is large, the warpage becomes less after the third step ST3. By the bonding step, a magnitude relationship between the warpage after the first step ST1 and the warpage after the third step ST3 is reversed.

When the absolute value of the first warping rate Wr1 after the first step ST1 is small, that is, when the absolute value of the third warping rate Wr3 after the third step ST3 is large, the compressive stress in the stacked body 15 is small. Conversely, when the absolute value of the first warping rate Wr1 after the first step ST1 is large, that is, when the absolute value of the third warping rate Wr3 after the third step ST3 is small, the compressive stress in the stacked body 15 (for example, the first semiconductor layer 10) is large. However, the third warping rate Wr3 after the third step ST3 is negative so that the compressive stress is applied to the stacked body 15.

In this manner, it is preferable that the third warping rate Wr3 is negative and the absolute value of the third warping rate Wr3 is small so as to provide a large compressive stress in the stacked body 15 (the first semiconductor layer 10). On the other hand, it is preferable that the first warping rate Wr1 is negative and the absolute value of the first warping rate Wr1 is large so as to provide a large compressive stress in the stacked body 15 (the first semiconductor layer 10). It is indicated that a magnitude relationship between an absolute value of the first warping rate Wr1 for providing a compressive stress and an absolute value of the third warping rate Wr3 for providing a compressive stress is reversed.

As shown in FIG. 6, a relationship between the first warping rate Wr1 and the third warping rate Wr3 is represented by, for example, a following formula (1).

Wr3=C1×Wr1+C2 (1)

A correlation between the first warping rate Wr1 and the third warping rate Wr3 shown in FIG. 6 is maintained even when a bonding temperature in a step (bonding between the substrate 70 and the processed body PB) shown in FIG. 3D is changed. That is, even if the bonding temperature is changed, a coefficient C1 is substantially constant, and is approximately −1.429. However, when the bonding temperature is changed, a coefficient C2 is changed.

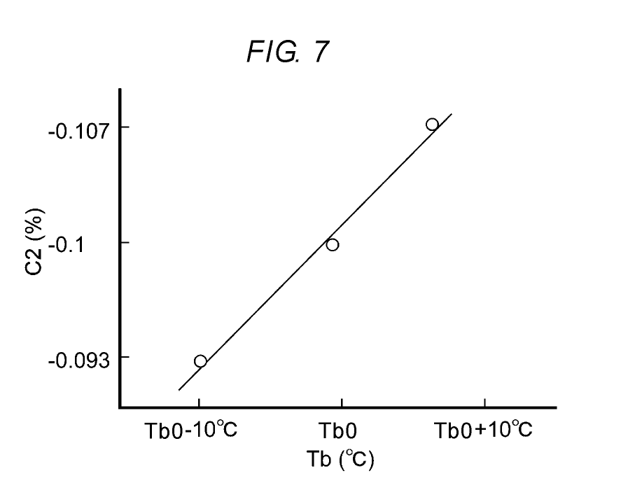

FIG. 7 is a graph that depicts a change in the relationship (change in the value of constant C2) of warpage at different points in the manufacturing with changes in processing temperature of the semiconductor light-emitting element according to the embodiment.

A horizontal axis in FIG. 7 represents a bonding temperature Tb (° C.). A condition that the bonding temperature Tb is a reference temperature Tb0 corresponds to the results of FIG. 6. In an example of FIG. 7, a result when the bonding temperature Tb (° C.) is (Tb0±10° C. is shown. A vertical axis in FIG. 7 represents a coefficient C2 of the (1) formula described above.

As shown in FIG. 7, when the bonding temperature Tb is high, an absolute value of the coefficient C2 is large, and when the bonding temperature Tb is low, the absolute value of the coefficient C2 is small. Based on a result of FIG. 7, it is indicated that the absolute value of the third warping rate Wr3 after the third step ST3 may become small according to the bonding temperature Tb even when the absolute value of the first warping rate Wr1 after the first step ST1 is large.

Accordingly, for example, by using an appropriate bonding condition, it is possible to obtain the third warping rate Wr3 of an appropriate absolute value and an appropriate compressive stress.

In the example embodiment, the bonding temperature is between 25° C. and 500° C. Bonding time is, for example, between 10 seconds and 3600 seconds.

### Second Embodiment

The second embodiment relates to a method of manufacturing a semiconductor light-emitting element.

In the manufacturing method, a surface (such as the fourth surface 15b) of the stacked body 15 on a side of the first semiconductor layer 10 is bonded to the substrate 70. The stacked body 15 includes the first semiconductor layer 10 provided on the substrate 50, the third semiconductor layer 30 provided on the first semiconductor layer 10, and the second semiconductor layer 20 provided on the third semiconductor layer. In the bonding process, the metal layer 75 is formed. That is, the processing described in relation to FIG. 3D is performed.

In the manufacturing method, after bonding, the substrate 50 is removed. That is, processing (the third step ST3) described in relation to FIG. 3E is performed.

After the removal of substrate 50, the surface (the fourth surface 15b) on a side of the first semiconductor layer has a concave shape. That is, for example, as shown in FIG. 4, the fourth surface 15b has a concave shape after the third step ST3.

As shown in FIG. 5, in the manufacturing method according to the embodiment, a lattice length (a measured value Lm) of the GaN layer 11 of the first semiconductor layer 10 in the second direction is smaller than a lattice constant Lc of GaN (bulk). In the GaN layer 11, a compressive stress is maintained, and defects or cracks hardly occur. Accordingly, high efficiency is obtained and changes in device characteristics due to cracking are suppressed, whereby higher device reliability is obtained.

“Nitride semiconductor” in the present disclosure is intended to include semiconductors of all compositions corresponding to the chemical formula BₓIn_{y}Al_{z}Ga_{1-x-y-z}N (0≦x≦1, 0≦y≦1, 0≦z≦1, x+y+z≦1). Furthermore, in the chemical formula described above, a semiconductor material further including Group V elements other than N (nitrogen), a semiconductor material further including various elements added (e.g., dopants) for controlling various physical properties such as conductivity and the like, and a semiconductor material including various elements other than those in the above chemical formula which may be unintentionally (e.g., trace impurities which are present in the material because they are technologically and/or economically unavoidable or otherwise not removable) included are included in the “nitride semiconductor.”

“Perpendicular” and “parallel” herein refers to not only strictly perpendicular and strictly parallel but also includes, for example, variation and the like in a manufacturing process, and may be substantially perpendicular and substantially parallel.

Embodiments have been described with reference to specific examples. However, the present disclosure is not limited to these specific examples. For example, other LED configurations of the semiconductor layer, the metal layers, electrode is within a scope of the present disclosure as long as the device may be realized in the same manner described in the disclosure and the same effect may be obtained by those skilled in the art appropriately selecting an element from a known technology range.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed:

1. A semiconductor light-emitting element, comprising:
a substrate having a first side and a second side;
a first semiconductor layer of a first conductivity type on the first side of the substrate;
a second semiconductor layer of a second conductivity type between the substrate and the first semiconductor layer;
a third semiconductor layer between the first semiconductor layer and the second semiconductor layer; and
a metal layer between the substrate and the second semiconductor layer, wherein
the substrate has a first surface on the first side facing the metal layer and a second surface on the second side of the substrate opposite the first surface, and
the second surface is convex.

2. The semiconductor light-emitting element according to claim 1,
wherein the first semiconductor layer includes a gallium nitride (GaN) layer, and
a lattice length perpendicular to a c-axis of the GaN layer is smaller than a lattice constant of bulk gallium nitride.

3. The semiconductor light-emitting element according to claim 2, further comprising:
a first electrode and a second electrode, wherein
a portion of the first semiconductor layer is provided between the first electrode and the metal layer,
the metal layer is electrically connected to the second semiconductor layer, and
the second electrode is electrically connected to the metal layer.

4. The semiconductor light-emitting element according to claim 1, further comprising:
a first electrode and a second electrode, wherein
a portion of the first semiconductor layer is provided between the first electrode and the metal layer,
the metal layer is electrically connected to the second semiconductor layer, and
the second electrode is electrically connected to the metal layer.

5. The semiconductor light-emitting element according to claim 4, wherein a distance between the first electrode and the metal layer is between 0.5 micrometers and 5 micrometers.

6. The semiconductor light-emitting element according claim 4, wherein the second electrode is directly contacting the metal layer on a surface of the metal layer that is facing away from the substrate.

7. The semiconductor light-emitting element according to claim 1, wherein the substrate comprises one of single crystal silicon, aluminum nitride, and a material of formula Al_{2-x-y}InₓGa_{y}O₃ (0≦x, y≦1).

8. The semiconductor light-emitting element according to claim 1, wherein the metal layer comprises at least one of nickel (Ni), silver (Ag), platinum (Pt), and tin (Sn).

9. A method of manufacturing a semiconductor light-emitting element, the method comprising:
forming a stacked semiconductor body on a first surface of a first substrate, the stacked body comprising a plurality of semiconductor layers covering the first surface of the first substrate, a second surface of the first substrate opposite the first surface of the first substrate being planar or concave after formation of the stacked body;
forming a metal layer on a first surface of the stacked body such that the stacked body is between the metal layer and the first substrate, the second surface of the first substrate being concave after formation of the metal layer;
bonding a second substrate to the first surface of the stacked body such that the metal layer is between the stacked body and the second substrate, the second surface of the first substrate being concave after bonding of the second substrate;
removing the first substrate to expose a second surface of the stacked body opposite the first surface of the stacked body, a second surface of the second substrate opposite a first surface of the second substrate that is facing the stacked body being convex and the second surface of the stacked body being concave after removal of the first substrate; and
removing portions of the stacked body and forming first and second electrodes for making electrical connections to layers in the plurality of semiconductor layers.

10. The method of claim 9, wherein the stacked body is maintained under a compressive stress while forming the metal layer, bonding the second substrate, and removing the first substrate.

11. The method of claim 9, wherein the stacked body includes a gallium nitride (GaN) layer and a lattice length of the GaN layer is smaller than a lattice constant of gallium nitride.

12. The method of claim 9, wherein the stacked body includes a first semiconductor layer, a light emitting layer on the first semiconductor layer, and a second semiconductor layer on the light emitting layer, such that the first semiconductor layer is nearest the first substrate and the second semiconductor layer is farthest from the first substrate.

13. The method of claim 12, wherein the light emitting layer is a multiple quantum well structure.

14. The method of claim 9, further comprising:
roughening the second surface of the stacked body after removal of the first substrate.

15. The method of claim 9, wherein removal of the first substrate removes a portion of the stacked body.

16. The method of claim 9, further comprising:
dicing the stacked body to form a plurality light emitting chips.

17. The method of claim 9, wherein the first substrate is a silicon wafer.

18. A method of manufacturing a semiconductor light emitting element, comprising:
forming a stacked body on a first substrate, the stacked body including a first semiconductor layer of a first conductivity type that is nearest the first substrate, a third semiconductor layer on the first semiconductor layer and configured to emit light when supplied with an electric current, and a second semiconductor layer of a second conductivity type on the third semiconductor layer such that the third semiconductor layer is between the first and second semiconductor layers; and
removing the first substrate after the forming of the stacked body, wherein a surface of the stacked body exposed by the removing of the first substrate has a concave shape.

19. The method of claim 18, wherein the first substrate is a silicon wafer and the first semiconductor layer includes a gallium nitride layer having a lattice length less than a lattice constant of gallium nitride.

20. The method of claim 18, further comprising:
bonding a second substrate to the stacked body such that the stacked body is between the first and second substrates before the removing of the first substrate.
